(19) United States
(12) Patent Application Publication
(10) Pub. No.: US 2026/0296076 A1
(43) Pub. Date: Oct. 1, 2026

(54) HEAT SINK, LIQUID DISCHARGE HEAD, AND LIQUID DISCHARGE APPARATUS

(71) Applicant: Kanako TAJIMA, Kanagawa (JP)

(72) Inventor: Kanako TAJIMA, Kanagawa (JP)

(21) Appl. No.: 19/567,470

(22) Filed: Mar. 16, 2026

(30) Foreign Application Priority Data
Mar. 25, 2025 (JP) 2025-049447
Jul. 18, 2025 (JP) 2025-120982

(51) Int. Cl. B41J 29/377; B41J 2/14; B41J 2/17; H05K 7/20

(52) U.S. Cl. CPC B41J 29/377; B41J 2/14233; B41J 2/1714; H05K 7/20409; B41J 2202/08

(57) ABSTRACT

A heat sink includes a wall portion and a liquid receiver. The wall portion is disposed on a side face of a liquid discharge head that discharges a liquid from nozzles in a discharge direction. The wall portion dissipates heat generated in the liquid discharge head. The liquid receiver is disposed at one end side region of the wall portion closer to the nozzles than another end side region of the wall portion in the discharge direction and projects from the wall portion in a transverse direction intersecting the discharge direction.

### CROSS-REFERENCE TO RELATED APPLICATIONS

This patent application is based on and claims priority pursuant to 35 U.S.C. § 119(a) to Japanese Patent Application Nos. 2025-049447, filed on Mar. 25, 2025, and 2025-120982, filed on Jul. 18, 2025, in the Japan Patent Office, the entire disclosure of each of which is hereby incorporated by reference herein.

### BACKGROUND

### Technical Field

The present disclosure relates to a heat sink for a liquid discharge head, a liquid discharge head, and a liquid discharge apparatus.

### Related Art

In the related art, a heat sink is used for a liquid discharge head.

### SUMMARY

The present disclosure described herein provides an improved heat sink including a wall portion and a liquid receiver. The wall portion is disposed on a side face of a liquid discharge head that discharges a liquid from nozzles in a discharge direction. The wall portion dissipates heat generated in the liquid discharge head. The liquid receiver is disposed at one end side region of the wall portion closer to the nozzles than another end side region of the wall portion in the discharge direction and projects from the wall portion in a transverse direction intersecting the discharge direction.

### BRIEF DESCRIPTION OF THE DRAWINGS

A more complete appreciation of embodiments of the present disclosure and many of the attendant advantages and features thereof can be readily obtained and understood from the following detailed description with reference to the accompanying drawings, wherein:

FIG. 1 is a schematic diagram illustrating a configuration of a printer;

FIG. 2 is a plan view of a discharge unit of the printer of FIG. 1;

FIG. 3 is a perspective view of an exterior of a liquid discharge head;

FIG. 4 is a cross-sectional view of a liquid discharge head taken in a direction orthogonal to a nozzle array direction;

FIG. 5 is a perspective view of an exterior of a liquid discharge head including a heat sink;

FIG. 6 is a perspective view of a heat sink;

FIGS. 7A and 7B are cross-sectional views of multiple heat-dissipation fins of a heat sink; and

FIG. 8 is a front view of heat-dissipation fins and auxiliary fins of a heat sink.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DETAILED DESCRIPTION

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a,” “an,” and “the” are intended to include the plural forms as well, unless the context clearly indicates otherwise.

A heat sink is used for a liquid discharge head. When a liquid discharge head discharges a liquid (ink), a mist of the liquid is generated, and the generated mist may adhere to the side face of the liquid discharge head. Such a mist adhering to the side face of the liquid discharge head may aggregate to form droplets, and the droplets may drip onto a medium.

In a comparative example, to prevent the droplets of the mist from falling onto the medium, a recessed portion for holding the droplets and a projecting portion for preventing the droplets that are not held in the recessed portion from falling onto the medium are disposed on a side face of the liquid discharge head.

However, in the comparative example, when the droplets of the mist are excessively accumulated in the projecting portion, the droplets of the mist may overflow from the projecting portion and drip onto the medium.

The present disclosure is made in view of the above-described situation, and an object of the present disclosure is to prevent the droplets of the mist from falling onto the medium.

A heat sink for a liquid discharge head, a liquid discharge head, and a liquid discharge apparatus are described in detail below with reference to the accompanying drawings.

### First Embodiment

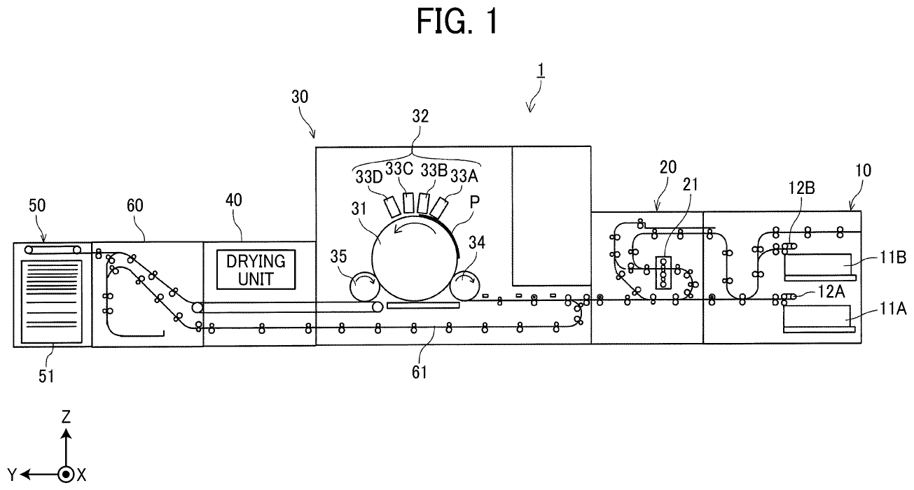

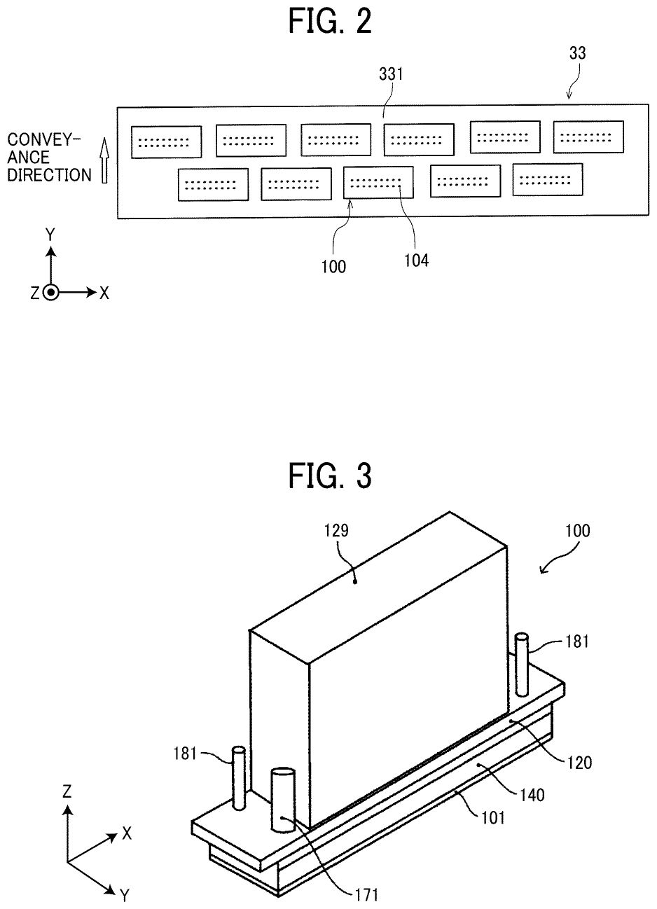

FIG. 1 is a schematic view of a printer 1, and FIG. 2 is a plan view of a discharge unit 33 of the printer 1.

The printer 1 as a liquid discharge apparatus includes a loading unit 10 to load a sheet P into the printer 1, a pretreatment unit 20, a printing unit 30, a drying unit 40, a reverse unit 60, and an ejection unit 50. In the printer 1, the pretreatment unit 20 applies, if desired, a pretreatment liquid onto the sheet P forwarded (supplied) from the loading unit 10, the printing unit 30 applies liquid (ink) to the sheet P to perform desired printing, the drying unit 40 dries the liquid (ink) adhering to the sheet P, and the sheet P is ejected to the ejection unit 50.

The loading unit 10 includes a lower loading tray 11A and an upper loading tray 11B to accommodate multiple sheets P and feeding units 12A and 12B to separate and forward the sheets P one by one from the lower and upper loading trays 11A and 11B, thereby supplying the sheets P to the pretreatment unit 20.

The pretreatment unit 20 includes, e.g., a coater 21 as a treatment-liquid application unit that coats a printing surface of the sheet P with a treatment liquid having an effect of aggregation of liquid (ink) to prevent bleed-through.

The printing unit 30 includes a drum 31 and a liquid discharge device 32. The drum 31 is a bearer (rotator) that bears the sheet P on a circumferential surface of the drum 31 and rotates. The liquid discharge device 32 discharges liquid (ink) toward the sheet P borne on the drum 31.

The printing unit 30 further includes transfer cylinders 34 and 35. The transfer cylinder 34 receives the sheet P from the pretreatment unit 20 and forwards the sheet P to the drum 31. The transfer cylinder 35 receives the sheet P conveyed by the drum 31 and forwards the sheet P to the drying unit 40.

The transfer cylinder 34 includes a sheet gripper to grip a leading end of the sheet P conveyed from the pretreatment unit 20 to the printing unit 30. The sheet P thus gripped is conveyed as the transfer cylinder 34 rotates. The transfer cylinder 34 forwards the sheet P to the drum 31 at a position opposite the drum 31.

Similarly, the drum 31 includes a sheet gripper on the surface of the drum 31, and the leading end of the sheet P is gripped by the sheet gripper of the drum 31. The drum 31 has a plurality of suction holes dispersedly on the surface of the drum 31, and a suction unit generates suction airflows directed inward from desired suction holes of the drum 31.

On the drum 31, the sheet gripper grips the leading end of the sheet P forwarded from the transfer cylinder 34, and the sheet P is attracted to and borne on the drum 31 by the suction airflows by the suction unit. As the drum 31 rotates, the sheet P is conveyed. In other words, the drum 31 is an example of a conveyor to convey the sheet P (i.e., a medium) to the liquid discharge device 32 including a liquid discharge head.

The liquid discharge device 32 includes discharge units 33 (i.e., discharge units 33A to 33D) to discharge liquids. For example, the discharge unit 33A discharges ink of cyan (C), the discharge unit 33B discharges ink of magenta (M), the discharge unit 33C discharges ink of yellow (Y), and the discharge unit 33D discharges ink of black (K). Further, the liquid discharge device 32 may include a discharge unit 33 that discharges special liquid, i.e., ink of spot color such as white, gold, or silver.

The discharge unit 33 is a full line head and includes, for example, multiple liquid discharge heads 100 disposed in a staggered arrangement on a base 331 as illustrated in FIG. 2. Each of the liquid discharge heads 100 has multiple nozzle arrays, and multiple nozzles 104 are arranged in each of the nozzle arrays. The liquid discharge head may be referred to simply as a “head” in the following description.

A discharge operation of each of the discharge units 33 of the liquid discharge device 32 is controlled by a drive signal corresponding to print data. When the sheet P borne on the drum 31 passes through a region facing the liquid discharge device 32, the liquids (inks) of respective colors are discharged from the discharge units 33, and an image corresponding to the print data is formed on the sheet P.

The drying unit 40 dries the liquid (ink) applied onto the sheet P by the printing unit 30. Thus, a liquid component such as moisture in the liquid (ink) evaporates, and the colorant contained in the liquid (ink) is fixed on the sheet P. Additionally, curling of the sheet P is prevented.

The reverse unit 60 reverses, in switchback manner, the sheet P that has passed through the drying unit 40 in duplex printing. The reversed sheet P is fed back to the upstream side of the transfer cylinder 34 through a conveyance passage 61 of the printing unit 30.

The ejection unit 50 includes an ejection tray 51 on which multiple sheets P are stacked. The multiple sheets P conveyed through the reverse unit 60 from the drying unit 40 are sequentially stacked and held on the ejection tray 51.

The liquid discharge head 100 will be described below in detail.

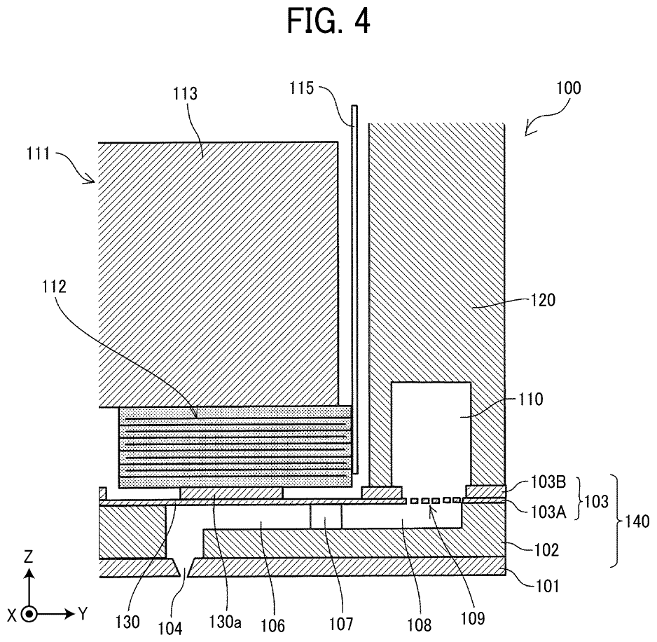

FIG. 3 is a perspective view of the exterior of the liquid discharge head 100, and FIG. 4 is a cross-sectional view of the liquid discharge head 100 in a direction (YZ plane) orthogonal to a nozzle array direction. In the following description, the longitudinal direction of the head is an X direction, the transverse direction of the head is a Y direction, and the height direction of the head (direction normal to a nozzle face on which multiple nozzles are arrayed) is a Z direction. The X direction, the Y direction, and the Z direction without plus or minus sign include both positive and negative directions. The X direction, the Y direction, and the Z direction are orthogonal to each other, or may intersects each other.

As illustrated in FIGS. 3 and 4, the liquid discharge head 100 includes a nozzle plate 101, a channel plate 102 as an individual channel member, and a diaphragm plate 103 as a wall member that are laminated one on another and bonded to each other as a structural portion. The liquid discharge head 100 further includes a piezoelectric actuator 111, a common chamber substrate 120, and a head cover 129. The piezoelectric actuator 111 as a pressure generator displaces a vibration portion (diaphragm) 130 of the diaphragm plate 103 to discharge liquid (ink) from multiple nozzles. The common chamber substrate 120 also serves as a frame of the liquid discharge head 100. A portion including the channel plate 102 and the diaphragm plate 103 is referred to as a channel substrate 140. The head cover 129 is disposed on the channel substrate 140 and covers the piezoelectric actuator 111 and other components. The nozzle plate 101 has the multiple nozzle arrays in which the multiple nozzles 104 are arrayed in the longitudinal direction to discharge liquid (ink).

The channel plate 102 has through holes and grooves that form multiple individual liquid chambers 106, which are pressure chambers communicating with the multiple nozzles 104, supply-side fluid restrictors 107 communicating with the individual liquid chambers 106, and liquid inlets 108 communicating with the supply-side fluid restrictors 107. The liquid inlets 108 communicate with a supply-side common liquid chamber 110 through openings 109 of the diaphragm plate 103.

The diaphragm plate 103 includes the multiple deformable vibration portions 130 serving as the wall of the individual liquid chambers 106 of the channel plate 102. The diaphragm plate 103 has, but is not limited to, a two-layer structure and includes a first layer 103A forming a thin portion and a second layer 103B forming a thick portion in this order from the channel plate 102. Portions of the first layer 103A corresponding to the individual liquid chambers 106 form the deformable vibration portions 130. The deformable vibration portions 130 are formed in the portions corresponding to the individual liquid chambers 106 in the first layer 103A serving as the thin portion. In the vibration portion 130, a projection 130a is formed as the thick portion joined to the piezoelectric actuator 111 in the second layer 103B.

The piezoelectric actuator 111 is disposed on the side opposite the individual liquid chamber 106 via the diaphragm plate 103. The piezoelectric actuator 111 includes an electromechanical transducer as a driving device (actuator device or pressure generator) to deform the vibration portion 130 of the diaphragm plate 103. The piezoelectric actuator 111 includes a piezoelectric element 112 bonded onto a base 113. The piezoelectric element 112 is grooved by, for example, half-cut dicing to form a comb shape including a desired number of pillar-shaped elements that are arranged at certain intervals. The piezoelectric element 112 is bonded to the projection 130a which is an island-shaped thick portion on the vibration portion 130 of the diaphragm plate 103. A flexible wiring 115 is connected to the piezoelectric element 112.

The common chamber substrate 120 defines the supply-side common liquid chamber 110 and a delivery-side common liquid chamber. The illustration of the delivery-side common liquid chamber is omitted in FIG. 4. The supply-side common liquid chamber 110 communicates with a supply port 171, and the delivery-side common liquid chamber communicates with a delivery port 181.

In the liquid discharge head 100, for example, the voltage to be applied to the piezoelectric element 112 is lowered from a reference potential (intermediate potential) so that the piezoelectric element 112 contracts to pull the vibration portion 130 of the diaphragm plate 103 to increase the volume of the individual liquid chamber 106. As a result, liquid (ink) flows into the individual liquid chamber 106. When the voltage applied to the piezoelectric element 112 is raised, the piezoelectric element 112 expands in the direction of lamination thereof. As a result, the vibration portion 130 of the diaphragm plate 103 deforms in the direction toward the nozzle 104 and contracts the volume of the individual liquid chamber 106. Thus, the liquid (ink) in the individual liquid chamber 106 is pressurized, and the liquid (ink) is discharged from the nozzle 104.

The liquid (ink) in the individual liquid chamber 106 that has not been discharged from the nozzle 104 is delivered to the delivery-side common liquid chamber through a delivery channel. Then, the liquid is delivered from the delivery-side common liquid chamber to an external liquid circulation path (e.g., a liquid circulation device) and supplied to the supply-side common liquid chamber 110 again through the external liquid circulation path. The method of driving the liquid discharge head is not limited to the above-described example (pull-push discharge). For example, pull discharge or push discharge may be performed in accordance with the way to apply a drive waveform.

In a liquid discharge head according to a comparative example, when liquid (ink) is discharged from the liquid discharge head, a mist of the liquid is generated, and the generated mist may adhere to a cover of the liquid discharge head (e.g., the head cover 129). Such a mist adhering to the cover may aggregate to form droplets and may drip onto a medium (sheet P).

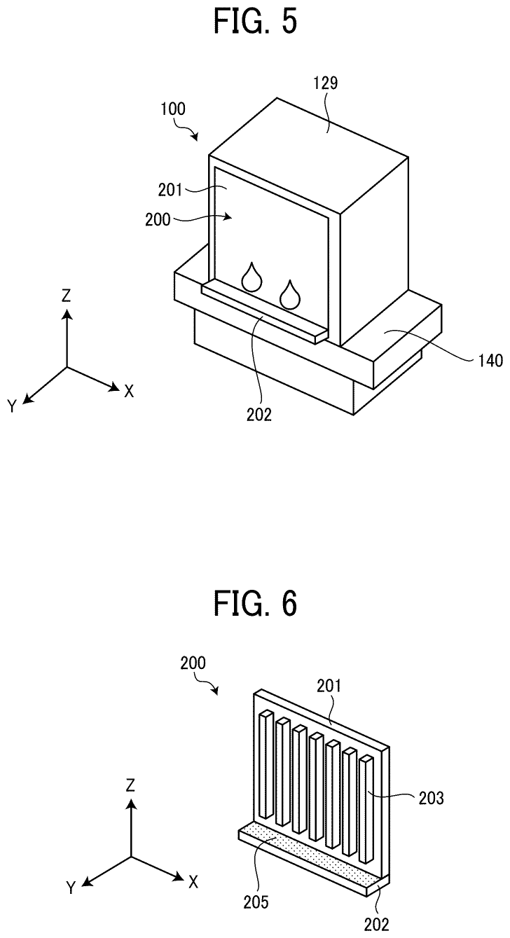

FIG. 5 is a perspective view of the exterior of the liquid discharge head 100 including a heat sink 200, and FIG. 6 is a perspective view of the heat sink 200. To prevent the droplets formed of the mist from dripping on the medium (sheet P), as illustrated in FIG. 5, the liquid discharge head 100 includes the heat sink 200, which is a heat sink for the liquid discharge head, on the head cover 129. The heat sink 200 is a component formed of a material having high thermal conductivity such as aluminum, and is a heat dissipation device (radiator) that more efficiently dissipates heat.

As illustrated in FIG. 5, the heat sink 200 is disposed on (attached to) at least one side face of the head cover 129 of the liquid discharge head 100. When the heat sink 200 is disposed on at least one side face of the head cover 129, heat generated in the liquid discharge head 100 is transferred to the heat sink 200, and the heat sink 200 dissipates the heat. Accordingly, the surface temperature of the heat sink 200, which is a heat dissipation device, rises. As a result, the drying of the liquid (ink) adhering to the surface of the heat sink 200 is accelerated, and thus the droplets of the liquid (ink) are prevented from falling onto the medium (sheet P).

As illustrated in FIG. 5, the heat sink 200 includes a liquid receiver 202 projecting from a flat wall portion 201 in the Y direction (i.e., the transverse direction) at one end side region of the wall portion 201 of the heat sink 200 in a droplet discharge direction (may be referred to simply as a discharge direction). The one end side region of the wall portion 201 is closer to the nozzles 104 than another end side region of the wall portion 201 in the discharge direction. For example, the liquid receiver 202 is disposed at the outermost end of the one end side region. The liquid receiver 202 disposed at the lower portion of the wall portion 201 can prevent the liquid (ink) from falling onto the medium (sheet P). The liquid receiver 202 preferably extends longer than the nozzle array of the multiple nozzles 104 in the longitudinal direction (X direction).

Further, as illustrated in FIG. 6, the heat sink 200 includes an absorber 205 on the upper face of the liquid receiver 202, which is a face (i.e., a first face) of the liquid receiver 202 facing another end side region opposite the one end side region of the wall portion 201 in the droplet discharge direction. In other words, the liquid receiver 202 has: the first face facing in an opposite direction to the discharge direction; and a second face opposite to the first face and closer to the nozzles 104 than the first face. The absorber 205 can absorb the liquid (ink). Examples of the absorber 205 include a polyolefin nonwoven cloth. As described above, the absorber 205 on the upper face of the liquid receiver 202 can retain a larger amount of liquid (ink) on the liquid receiver 202, and thus the droplets of the liquid (ink) are prevented from falling onto the medium (sheet P).

As illustrated in FIG. 6, the heat sink 200 includes multiple heat-dissipation fins 203 arranged in the X direction (i.e., the longitudinal direction) and in parallel with the vertical direction (Z direction), projecting from the surface of the flat wall portion 201 in the Y direction, and extending in the Z direction. The heat-dissipation fins 203 are also formed of a material having high thermal conductivity such as aluminum. The length (width) of the heat-dissipation fin 203 in the Y direction (i.e., a second length) is shorter than the length (width) of the liquid receiver 202 in the Y direction (i.e., a first length). The length in the Y direction may be referred to as a projecting length.

When the liquid discharge head 100 is used while being inclined toward the liquid receiver 202 of the heat sink 200, the liquid receiver 202 of the heat sink 200 alone is not sufficient to prevent the liquid (ink) from falling onto the medium (sheet P).

Accordingly, in the heat sink 200, the multiple heat-dissipation fins 203 are arranged at intervals to retain the liquid (ink) in a gap between the multiple heat-dissipation fins 203 by capillarity. As a result, the heat sink 200 prevents the liquid (ink) from falling onto the medium (sheet P).

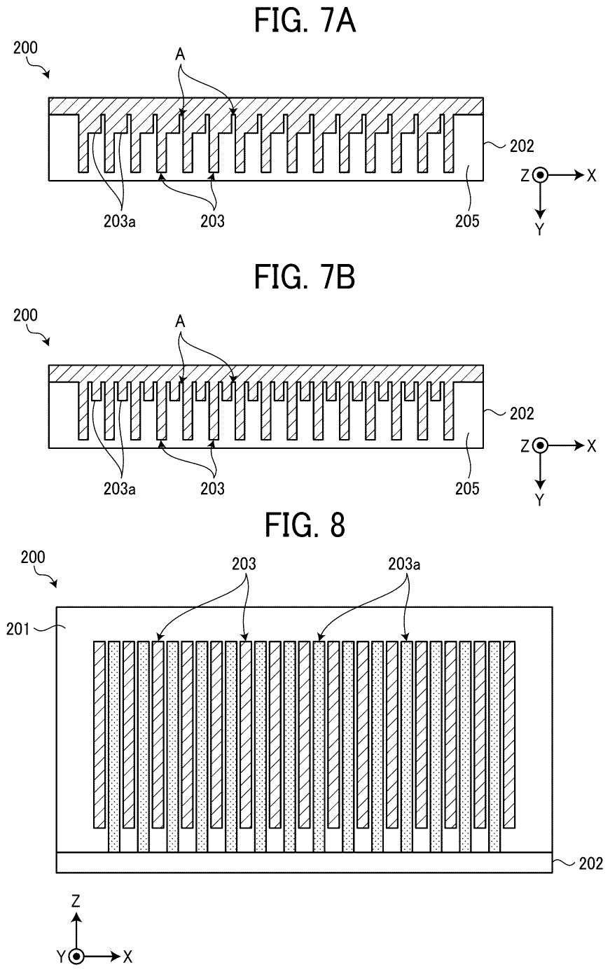

FIGS. 7A and 7B are cross-sectional views of the multiple heat-dissipation fins 203 of the heat sink 200, illustrating a configuration thereof.

When the liquid (ink) is retained by capillarity by the multiple heat-dissipation fins 203, if the interval between the multiple heat-dissipation fins 203 is narrowed to the extent that the capillarity occurs in the entire area, the airflow resistance between the heat-dissipation fins 203 increases. As a result, the performance of the heat sink 200 (heat sink performance) may not be exhibited well.

For this reason, as illustrated in FIG. 7A, the heat sink 200 further includes auxiliary fins 203a integrally projecting from the wall portion 201 with the heat-dissipation fins 203 at the joint portion between the heat-dissipation fins 203 and the wall portion 201, respectively. Liquid (ink) is retained (held) by a part of the region of the heat-dissipation fins 203, i.e., the joint portion between the heat-dissipation fins 203 and the wall portion 201, which may be referred to as an ink holding region (capillarity region) A or simply as a holding region. The length of the auxiliary fin 203a in the Y direction is shorter than the length of the heat-dissipation fin 203 in the Y direction. The auxiliary fin 203a has a certain length (width) in the X direction so as to form a gap that allows liquid to be retained (held) between the adjacent heat-dissipation fins 203 by capillarity. With such a configuration, the ink retention performance and the heat sink performance can be optimized. In particular, since the ink holding region (capillarity region) A is formed at the joint portion between the heat-dissipation fins 203 and the wall portion 201, even if liquid (ink) falls from the joint portion between the heat-dissipation fins 203 and the wall portion 201 while an airflow is generated, the liquid (ink) drips along the wall portion 201 or falls onto the liquid receiver 202 (absorber 205). Accordingly, the liquid (ink) can be further prevented from falling onto the medium (sheet P).

As illustrated in FIG. 7B, the heat sink 200 may include auxiliary fins 203a between the heat-dissipation fins 203, respectively, to form the ink holding region (capillarity region) A between the adjacent heat-dissipation fins 203 and both sides of the auxiliary fin 203a. By so doing, a larger amount of liquid (ink) can be retained.

As described above, the droplets formed of a mist can be prevented from falling onto the medium.

### Second Embodiment

A description is given below of a second embodiment of the present disclosure.

In the second embodiment, the shape of the heat sink 200 is different from that of the first embodiment. In the following description of the second embodiment, descriptions of elements identical or similar to those in the first embodiment are omitted, and differences from the first embodiment are described.

FIG. 8 is a front view of the heat-dissipation fins 203 and the auxiliary fins 203a of the heat sink 200 according to the second embodiment.

As illustrated in FIG. 8, in the heat sink 200, the auxiliary fin 203a that forms the ink holding region (capillary region) A is longer in the Z direction than the heat-dissipation fin 203 so that the liquid (ink) reliably drips onto the liquid receiver 202 (absorber 205).

More specifically, in the heat sink 200, the auxiliary fin 203a extends to the vicinity of the liquid receiver 202 (the absorber 205), or reaches the liquid receiver 202 (the absorber 205) so that the auxiliary fin 203a contacts the liquid receiver 202.

Accordingly, the liquid (ink) retained (held) in the ink holding region (capillarity region) A drips along the wall portion 201 or the auxiliary fin 203a, or reliably falls onto the liquid receiver 202 (absorber 205). Accordingly, the liquid (ink) can be further prevented from falling onto the medium (sheet P).

In the present disclosure, the liquid to be discharged is not limited to a particular liquid as long as the liquid has a viscosity or surface tension to be discharged from a head (liquid discharge head). However, preferably, the viscosity of the liquid is not greater than 30 millipascal-second (mPa·s) under ordinary temperature and ordinary pressure or by heating or cooling. More specifically, examples of the liquid to be discharged include a solution, a suspension, or an emulsion including, for example, a solvent, such as water or an organic solvent; a colorant, such as dye or pigment; a functional material, such as a polymerizable compound, a resin, or a surfactant; a biocompatible material, such as deoxyribonucleic acid (DNA), amino acid, protein, or calcium; and an edible material, such as a natural colorant. Such a solution, a suspension, or an emulsion can be used for, e.g., inkjet ink; surface treatment liquid; a liquid for forming an electronic element component, a light-emitting element component, or an electronic circuit resist pattern; or a material solution for three-dimensional fabrication.

Examples of an energy source for generating energy to discharge liquid include a piezoelectric actuator (a laminated piezoelectric element or a thin-film piezoelectric element), a thermal actuator that employs a thermoelectric transducer, such as a thermal resistor, and an electrostatic actuator including a diaphragm and opposed electrodes.

The “liquid discharge unit” is an assembly of parts relating to liquid discharge. The term “liquid discharge unit” represents a structure including the liquid discharge head and a functional component(s) or mechanism(s) combined with the liquid discharge head as a single unit. For example, the “liquid discharge unit” includes a combination of the liquid discharge head with at least one of a head tank, a carriage, a supply mechanism, a maintenance mechanism, a main-scanning moving mechanism, or a liquid circulation device.

The above integration may be achieved by, for example, a combination in which the liquid discharge head and a functional component(s) or mechanism(s) are fixed to each other through, e.g., fastening, bonding, or engaging, and a combination in which one of the liquid discharge head and the functional component(s) or mechanism(s) is movably held to the other. The liquid discharge head, the functional components, and the mechanisms may be detachably attached to each other.

For example, the liquid discharge head and the head tank are integrated to form the liquid discharge unit as a single unit. Alternatively, the liquid discharge head and the head tank coupled (connected) to each other via, for example, a tube may form the liquid discharge unit as a single unit. A unit including a filter may further be added to a portion between the head tank and the liquid discharge head of the liquid discharge unit.

In another example, the liquid discharge unit may be an integrated unit in which a liquid discharge head is integrated with a carriage.

As yet another example, the liquid discharge unit is a unit in which the liquid discharge head and the main-scanning moving mechanism are combined into a single unit. The liquid discharge head is movably held by a guide that is a part of the main-scanning moving mechanism. The liquid discharge unit may include the liquid discharge head, the carriage, and the main-scanning moving mechanism that are integrated as a single unit.

In another example, a cap that forms a part of the maintenance mechanism is fixed to the carriage mounting the liquid discharge head so that the liquid discharge head, the carriage, and the maintenance mechanism are integrated as a single unit to form the liquid discharge unit.

Further, in still another example, the liquid discharge unit includes tubes connected to the liquid discharge head mounting the head tank or the channel component so that the liquid discharge head and the supply mechanism are integrated as a single unit. Through the tube, the liquid in a liquid storage source is supplied to the liquid discharge head.

The main-scanning moving mechanism may be a guide only. The supply mechanism may be a tube(s) only or a loading device only.

The term “liquid discharge apparatus” used herein also represents an apparatus including the liquid discharge head or the liquid discharge unit to drive the liquid discharge head to discharge liquid. The liquid discharge apparatus may be, for example, any apparatus that can discharge liquid to a medium onto which liquid can adhere or any apparatus to discharge liquid toward gas or into a different liquid.

The “liquid discharge apparatus” may further include devices relating to feeding, conveying, and ejecting of the medium onto which liquid can adhere and also include a pretreatment device and an aftertreatment device.

The “liquid discharge apparatus” may be, for example, an image forming apparatus to form an image on a sheet by discharging ink, or a three-dimensional fabrication apparatus to discharge fabrication liquid to a powder layer in which powder material is formed in layers, so as to form a three-dimensional object.

The “liquid discharge apparatus” is not limited to an apparatus that discharges liquid to visualize meaningful images such as letters or figures. For example, the discharge apparatus may be an apparatus that forms patterns having no meaning or an apparatus that fabricates three-dimensional images.

The above-described term “medium onto which liquid can adhere” represents a medium on which liquid is at least temporarily adhered, a medium on which liquid is adhered and fixed, or a medium into which liquid adheres and permeates. Specific examples of the “medium onto which liquid can adhere” include, but are not limited to, a recording medium such as a paper sheet, recording paper, a recording sheet of paper, a film, or cloth, an electronic component such as an electronic substrate or a piezoelectric element, and a medium such as layered powder, an organ model, or a testing cell. The “medium onto which liquid can adhere” includes any medium to which liquid adheres, unless otherwise specified.

Examples of materials for the “medium onto which liquid can adhere” include any materials to which liquid can adhere even temporarily, such as paper, thread, fiber, fabric, leather, metal, plastic, glass, wood, and ceramic.

The liquid discharge apparatus may be an apparatus to move the liquid discharge head and the medium onto which liquid can adhere relative to each other. However, the liquid discharge apparatus is not limited to such an apparatus. For example, the liquid discharge apparatus may be a serial head apparatus that moves the liquid discharge head or a line head apparatus that does not move the liquid discharge head.

Examples of the liquid discharge apparatus further include: a treatment liquid applying apparatus that discharges a treatment liquid onto a sheet to apply the treatment liquid to the surface of the sheet, for reforming the surface of the sheet; and an injection granulation apparatus that injects a composition liquid, in which a raw material is dispersed in a solution, through a nozzle to granulate fine particles of the raw material.

The terms “image formation,” “recording,” “printing,” “image printing,” and “fabricating” used herein may be used synonymously with each other.

Aspects of the present disclosure are, for example, as follows.

### Aspect 1

A heat sink for a liquid discharge head, includes a flat wall portion and a liquid receiver. The flat wall portion is disposed on at least one side face of a head cover covering a pressure generator that causes the liquid discharge head to discharge a liquid from a nozzle array. The wall portion dissipates heat. The liquid receiver is disposed at an end of the wall portion in a droplet discharge direction or on an end side of the wall portion in the droplet discharge direction. The liquid receiver projects from the wall portion.

In other words, a heat sink includes a wall portion and a liquid receiver. The wall portion is disposed on a side face of a liquid discharge head that discharges a liquid from nozzles in a discharge direction. The wall portion dissipates heat generated in the liquid discharge head. The liquid receiver is disposed at one end side region of the wall portion closer to the nozzles than another end side region of the wall portion in the discharge direction and projects from the wall portion in a transverse direction intersecting the discharge direction.

Further, the liquid receiver is disposed at the outermost end of the one end side region in the discharge direction.

The liquid receiver extends in a longitudinal direction of the liquid discharge head intersecting the discharge direction and the transverse direction.

In addition, the nozzles are arrayed in the longitudinal direction, and the liquid receiver extends longer than a nozzle array of the nozzles in the longitudinal direction.

### Aspect 2

The heat sink for the liquid discharge head according to Aspect 1, further includes an absorber disposed on an upper face of the liquid receiver to absorb the liquid.

In other words, the liquid receiver includes an absorber to absorb the liquid on the liquid receiver. The liquid receiver has: a first face facing in an opposite direction to the discharge direction; and a second face opposite to the first face and closer to the nozzles than the first face. The absorber is disposed on the first face.

### Aspect 3

The heat sink for a liquid discharge head according to Aspect 1 or 2, further includes multiple heat-dissipation fins that are erected on a surface of the wall portion in a vertical direction to dissipate the heat. The multiple heat-dissipation fins have a projecting length shorter than a projecting length of the liquid receiver.

In other words, the wall portion includes multiple heat-dissipation fins to dissipate the heat. The multiple heat-dissipation fins are arranged in a longitudinal direction of the liquid discharge head intersecting the discharge direction and the transverse direction. Each of the multiple heat-dissipation fins: extends in the discharge direction; and projects from the wall portion in the transverse direction. The liquid receiver projects from the wall portion with a first length in the transverse direction. Each of the multiple heat-dissipation fins projects from the wall portion with a second length shorter than the first length of the liquid receiver in the transverse direction.

### Aspect 4

In the heat sink for the liquid discharge head according to Aspect 3, the multiple heat-dissipation fins are erected at intervals to retain the liquid by capillarity.

In other words, the multiple heat-dissipation fins are arranged at intervals in a longitudinal direction of the liquid discharge head intersecting the discharge direction and the transverse direction to retain the liquid in a gap between the multiple heat-dissipation fins by capillarity.

### Aspect 5

In the heat sink for the liquid discharge head according to Aspect 4, the multiple heat-dissipation fins can retain the liquid by capillarity in a holding region formed by a part of the heat-dissipation fins.

In other words, each of the multiple heat-dissipation fins has a holding region in a part of the multiple heat-dissipation fins to retain the liquid in the gap between the multiple heat-dissipation fins by capillarity.

### Aspect 6

In the heat sink for the liquid discharge head according to Aspect 5, the holding region that can retain the liquid by capillarity is disposed at a joint portion between the multiple heat-dissipation fins and the wall portion.

In other words, each of the multiple heat-dissipation fins has the holding region at a joint portion between the multiple heat-dissipation fins and the wall portion in the transverse direction.

### Aspect 7

The heat sink for the liquid discharge head according to Aspect 5 or 6, further includes auxiliary fins that are erected between the multiple heat-dissipation fins, respectively, to form the holding region between both sides of the heat-dissipation fins and the heat-dissipation fins.

In other words, the heat sink according to claim 6, further includes auxiliary fins projecting from the wall portion between the multiple heat-dissipation fins, respectively. The holding region is disposed between both sides of each of the auxiliary fins and adjacent heat-dissipation fins of the multiple heat-dissipation fins.

### Aspect 8

In the heat sink for the liquid discharge head according to Aspect 7, the auxiliary fins are formed longer than the heat-dissipation fins.

In other words, the auxiliary fins are longer in the discharge direction than the multiple heat-dissipation fins.

### Aspect 9

In the heat sink for the liquid discharge head according to Aspect 8, the auxiliary fins reach the liquid receiver.

In other words, the auxiliary fins reach the liquid receiver in the discharge direction.

### Aspect 10

A liquid discharge head includes a pressure generator to discharge a desired liquid from a nozzle row, a head cover that covers the pressure generator, and the heat sink for the liquid discharge head according to any one of Aspects 1 to 9.

In other words, a liquid discharge head includes: a nozzle plate having a nozzle array having the nozzles; a pressure generator to discharge the liquid from the nozzles; a head cover covering the pressure generator; and the heat sink, according to any one of Aspects 1 to 9, attached to the side face of the head cover.

### Aspect 11

A liquid discharge apparatus includes the liquid discharge head according to Aspect 10, to drive the liquid discharge head to discharge the liquid.

In other words, a liquid discharge apparatus includes: the liquid discharge head according to Aspect 10, to discharge the liquid onto a medium; and a conveyor to convey the medium to the liquid discharge head.

As described above, according to one aspect of the present disclosure, an effect of preventing the droplets of mist from falling onto a medium can be achieved.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention.

1. A heat sink comprising:
a wall portion disposed on a side face of a liquid discharge head that discharges a liquid from nozzles in a discharge direction,
the wall portion to dissipate heat generated in the liquid discharge head; and
a liquid receiver:
disposed at one end side region of the wall portion closer to the nozzles than another end side region of the wall portion in the discharge direction;
projecting from the wall portion in a transverse direction intersecting the discharge direction.

2. The heat sink according to claim 1,
wherein the liquid receiver is disposed at the outermost end of the one end side region in the discharge direction.

3. The heat sink according to claim 1,
wherein the liquid receiver extends in a longitudinal direction of the liquid discharge head intersecting the discharge direction and the transverse direction.

4. The heat sink according to claim 3,
wherein the nozzles are arrayed in the longitudinal direction, and
the liquid receiver extends longer than a nozzle array of the nozzles in the longitudinal direction.

5. The heat sink according to claim 1,
wherein the liquid receiver includes an absorber to absorb the liquid on the liquid receiver,
the liquid receiver has:
a first face facing in an opposite direction to the discharge direction; and
a second face opposite to the first face and closer to the nozzles than the first face, and
the absorber is on the first face.

6. The heat sink according to claim 1,
wherein the wall portion includes multiple heat-dissipation fins to dissipate the heat,
the multiple heat-dissipation fins are arranged in a longitudinal direction of the liquid discharge head intersecting the discharge direction and the transverse direction,
each of the multiple heat-dissipation fins:
extends in the discharge direction; and
projects from the wall portion in the transverse direction, and
the liquid receiver projects from the wall portion with a first length in the transverse direction; and
each of the multiple heat-dissipation fins projects from the wall portion with a second length shorter than the first length of the liquid receiver in the transverse direction.

7. The heat sink according to claim 6,
wherein the multiple heat-dissipation fins are arranged at intervals in a longitudinal direction of the liquid discharge head intersecting the discharge direction and the transverse direction,
to retain the liquid in a gap between the multiple heat-dissipation fins by capillarity.

8. The heat sink according to claim 7,
wherein each of the multiple heat-dissipation fins has a holding region in a part of the multiple heat-dissipation fins to retain the liquid in the gap between the multiple heat-dissipation fins by capillarity.

9. The heat sink according to claim 8,
wherein each of the multiple heat-dissipation fins has the holding region at a joint portion between the multiple heat-dissipation fins and the wall portion in the transverse direction.

10. The heat sink according to claim 8, further comprising auxiliary fins projecting from the wall portion between the multiple heat-dissipation fins, respectively, and
the holding region is disposed between both sides of each of the auxiliary fins and adjacent heat-dissipation fins of the multiple heat-dissipation fins.

11. The heat sink according to claim 10,
wherein the auxiliary fins are longer in the discharge direction than the multiple heat-dissipation fins.

12. The heat sink according to claim 11, wherein the auxiliary fins reach the liquid receiver in the discharge direction.

13. A liquid discharge head comprising:
a nozzle plate having a nozzle array having the nozzles;
a pressure generator to discharge the liquid from the nozzles;
a head cover covering the pressure generator; and
the heat sink, according to claim 1, attached to the side face of the head cover.

14. A liquid discharge apparatus comprising:
the liquid discharge head according to claim 13, to discharge the liquid onto a medium; and
a conveyor to convey the medium to the liquid discharge head.
